(19) United States
(12) Patent Application Publication
(10) Pub. No.: US 2013/0243113 A1
(43) Pub. Date: Sep. 19, 2013

(54) GENERATING AND ROUTING A SUB-HARMONIC OF A LOCAL OSCILLATOR SIGNAL

(71) Applicant: QUALCOMM INCORPORATED, San Diego, CA (US)

(72) Inventor: Mazhareddin Taghivand, Campbell, CA (US)

(73) Assignee: QUALCOMM INCORPORATED, San Diego, CA (US)

(21) Appl. No.: 13/762,235

(22) Filed: Feb. 7, 2013

Related U.S. Application Data
(60) Provisional application No. 61/612,031, filed on Mar. 16, 2012.

(51) Int. Cl. H03L 7/20

(52) U.S. Cl. CPC H03L 7/20
USPC 375/295; 331/18

(57) ABSTRACT

A particular apparatus for generating a local oscillator (LO) signal includes a phase-locked loop (PLL) configured to output a signal having a frequency that is a sub-harmonic of a LO frequency. The apparatus also includes a mixer block having a frequency upconverter configured to upconvert the signal to generate a LO signal having the LO frequency. For example, the PLL may be integrated into a multiple-input multiple-output (MIMO) device and may generate the sub-harmonic signal. The sub-harmonic signal may be routed to each of a plurality of mixer blocks of the MIMO device. Each of the mixer blocks may upconvert the sub-harmonic signal to generate the LO signal.

### CROSS-REFERENCE TO RELATED APPLICATIONS

The present application claims priority from commonly owned U.S. Provisional Patent Application No. 61/612,031 filed on Mar. 16, 2012, the contents of which are expressly incorporated herein by reference in their entirety.

### BACKGROUND

1. Field

The present disclosure relates to frequency generation in electronic devices.

2. Background

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and Internet Protocol (IP) telephones, can communicate voice and data packets over wireless networks. Many such wireless telephones incorporate additional devices to provide enhanced functionality for end users. For example, a wireless telephone can also include a digital still camera, a digital video camera, a digital recorder, and an audio file player. Also, such wireless telephones can execute software applications, such as a web browser application that can be used to access the Internet. As such, these wireless telephones can include significant computing capabilities.

In an electronic device, such as a wireless telephone, a local oscillator (LO) frequency may be used to perform signal processing operations (e.g., at a transceiver of the wireless telephone). The LO frequency may depend on the frequency of a wireless channel that is in use. A phase-locked loop (PLL) may be used to generate the LO frequency. As high frequency channels become more common, higher LO frequencies may be needed to perform operations at the wireless telephone. However, it may be difficult to design a PLL to keep up with increasing LO frequency requirements due to process/voltage/temperature (PVT) variations experienced by the PLL. To illustrate, a high frequency PLL may not meet tuning, noise, or power consumption requirements. In addition, routing of high LO frequency signals to various components of the wireless telephone may consume an unacceptably high amount of battery power.

### SUMMARY

Systems and methods of generating a LO frequency by upconversion (e.g., multiplication) of a sub-harmonic frequency are disclosed. For example, the described techniques may be applied in multiple-input multiple-output (MIMO) devices that utilize a LO frequency of approximately 60 gigahertz (GHz). To illustrate, the MIMO devices may be compatible with an Institute of Electrical and Electronics Engineers (IEEE) 802.11ad protocol, in which four wireless channels exist between 57 GHz and 66 GHz. The described techniques may also be used with other standards that support MIMO, as well as standards without MIMO.

To generate a high frequency (e.g., 60 GHz) LO signal, the described techniques may first generate a lower frequency sub-harmonic of the desired LO signal. For example, a 15 GHz or 20 GHz sub-harmonic of the desired 60 GHz signal may be generated using a PLL. At a routing endpoint (e.g., front-end mixer blocks of a MIMO device), the sub-harmonic signal may be multiplied to generate the LO signal. Generating and routing the sub-harmonic signal instead of the LO signal may relax PLL design requirements and use less power at the PLL. Moreover, routing the sub-harmonic signal instead of the LO signal to the routing endpoints may use less power at an electronic device. Use of sub-harmonic signals may also provide increased immunity to frequency pulling effects, electromagnetic and substrate coupling (e.g., to sensitive blocks, such as a low noise amplifier (LNA)), and PVT variations in phase or amplitude experienced by in-phase/quadrature-phase (I/Q) signals in a MIMO device.

Unlike superheterodyne architectures that attempt to generate a 60 GHz signal using a conversion to an intermediate frequency (e.g., 48 GHz), the disclosed system and method may use a single homodyne (also referred to as zero-IF) conversion to generate frequencies at or near all four wireless channel frequencies of 802.11ad over potential PVT variations. In some implementations, the LO frequency generation and routing techniques disclosed herein may be used in conjunction with a superheterodyne architecture. For example, a 12 GHz sub-harmonic signal may be generated and routed in a 48 GHz superheterodyne system.

In a particular embodiment, an apparatus for generating a LO signal includes a PLL configured to output a signal having a frequency that is a sub-harmonic of a LO frequency. The apparatus also includes a mixer blocking having a frequency upconverter configured to upconvert the signal to generate a LO signal having the LO frequency.

In another particular embodiment, an apparatus for generating a LO signal includes a MIMO device including a PLL configured to output a signal having a frequency that is a sub-harmonic of a LO frequency. The MIMO device also includes a plurality of mixer blocks, where each mixer block is associated with a particular input and a particular output of the MIMO device. Each mixer block includes a frequency upconverter configured to upconvert the signal to generate a LO signal having the LO frequency. The MIMO device further includes a plurality of sub-harmonic transmission paths, where each sub-harmonic transmission path is configured to route the signal to a mixer block of the plurality of mixer blocks.

In another particular embodiment, a method for generating a LO signal includes generating, at a PLL of an electronic device, a signal having a frequency that is a sub-harmonic of a LO frequency of the electronic device. The method also includes upconverting the signal at a mixer block to generate a LO signal having the LO frequency.

In another particular embodiment, a method for generating a LO signal includes generating, at a PLL of a MIMO device, a signal having a frequency that is a sub-harmonic of a LO frequency of the MIMO device. The method also includes routing the signal to each of a plurality of mixer blocks of the MIMO device via a corresponding one of a plurality of sub-harmonic transmission paths of the MIMO device. The method further includes upconverting the signal at each of the plurality of mixer blocks to generate a LO signal having the LO frequency at each of the plurality of mixer blocks.

One particular advantage provided by at least one of the disclosed embodiments is an ability to generate a sub-harmonic frequency signal at a PLL and route the sub-harmonic frequency signal to endpoints such as front-end mixer blocks of a MIMO device, which locally upconvert the sub-harmonic frequency signal to generate a LO frequency signal. Generating and routing the sub-harmonic frequency signal instead of the LO frequency signal may simplify design and conserve power at the MIMO device.

Other aspects, advantages, and features of the present disclosure will become apparent after review of the entire application, including the following sections: Brief Description of the Drawings, Detailed Description, and the Claims.

### BRIEF DESCRIPTION OF THE DRAWINGS

FIG. 1 is a diagram of a particular embodiment of a system that is operable to generate a LO frequency by upconversion of a sub-harmonic frequency;

FIG. 2 is a diagram of a particular embodiment of a MIMO device that is operable to generate a LO frequency at each of a plurality of front-end mixer blocks by upconversion of a sub-harmonic frequency generated by a PLL;

FIG. 3 is a diagram to illustrate a particular embodiment of a system that is operable to upconvert a sub-harmonic frequency to generate a LO frequency;

FIG. 4 is a diagram to illustrate a circuit-level implementation of the system of FIG. 3;

FIG. 5 is a flowchart of a particular embodiment of a method of generating a LO frequency by upconversion of a sub-harmonic frequency;

FIG. 6 is a flowchart of another particular embodiment of a method of generating a LO frequency by upconversion of a sub-harmonic frequency; and

FIG. 7 is a block diagram of a mobile communication device including components that are operable to generate a LO frequency by upconversion of a sub-harmonic frequency.

### DETAILED DESCRIPTION

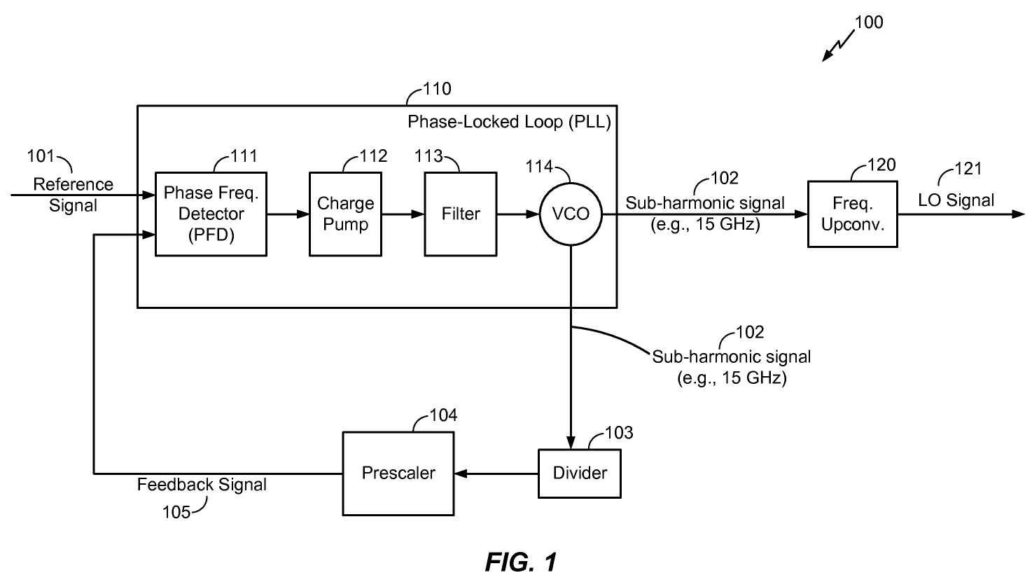

FIG. 1 is a diagram of a particular embodiment of a system 100 that is operable to generate a LO frequency by upconversion of a sub-harmonic frequency. The system includes a phase-locked loop (PLL) 110 coupled to a frequency upconverter 120. A feedback path of the PLL 110 includes a divider 103 and a prescaler (e.g., N divider) 104. It should be noted that although an integer N PLL is described herein, this is for illustration only. In alternate embodiments, another type of PLL may be used, such as a digital PLL (DPLL), a fractional-N (Frac-N) PLL, a Frac-N PLL with Sigma-Delta, etc.

The PLL 110 may include a phase frequency detector (PFD) 111 that receives a reference signal 101 having a reference frequency. In a particular embodiment, the reference signal 101 is provided by a system clock. The PFD 111 may also receive a feedback signal 105 from the prescaler 104. The PFD 111 may be configured to detect if and by how much the feedback signal 105 deviates from the reference signal 101. For example, the reference signal 101 may have a frequency of 100 megahertz (MHz) and the PFD 111 may determine if and by how much the feedback signal 105 is less than or greater than 100 MHz. It should be noted that the description of 100 MHz as a reference frequency is for illustration only. In alternate embodiments, other reference frequencies may be used.

The PLL 110 may also include a charge pump 112 and a filter 113 (e.g., a low pass filter) connected between the PFD 111 and an oscillator 114. In the embodiment of FIG. 1, the oscillator 114 is a voltage-controlled oscillator (VCO). In alternate embodiments, the oscillator 114 may be a current-controlled oscillator (CCO) or a digitally-controlled oscillator (DCO). The oscillator 114 may be configured to generate a signal 102. The signal 102 may be a sub-harmonic signal having a frequency that is a sub-harmonic of a LO frequency of the system 100. For example, the LO frequency may be 60 GHz and the sub-harmonic signal 102 may be a 15 GHz sub-harmonic signal (i.e., a 1/4 sub-harmonic). It should be noted that the description of a 1/4 sub-harmonic is for illustration only. The sub-harmonic signal 102 may by any 1/n sub-harmonic of the LO frequency, where n is an integer greater than or equal to 2.

The oscillator 114 may output the sub-harmonic signal 102 to the divider 103 coupled to the prescaler 104. The combination of the divider 103 and the prescaler 104 may frequency downconvert the sub-harmonic signal 102 to generate the feedback signal 105. For example, a 15 GHz sub-harmonic signal may be downconverted to an approximately 100 MHz feedback signal, and any deviation from 100 MHz may be detected by the PFD 111, as described above.

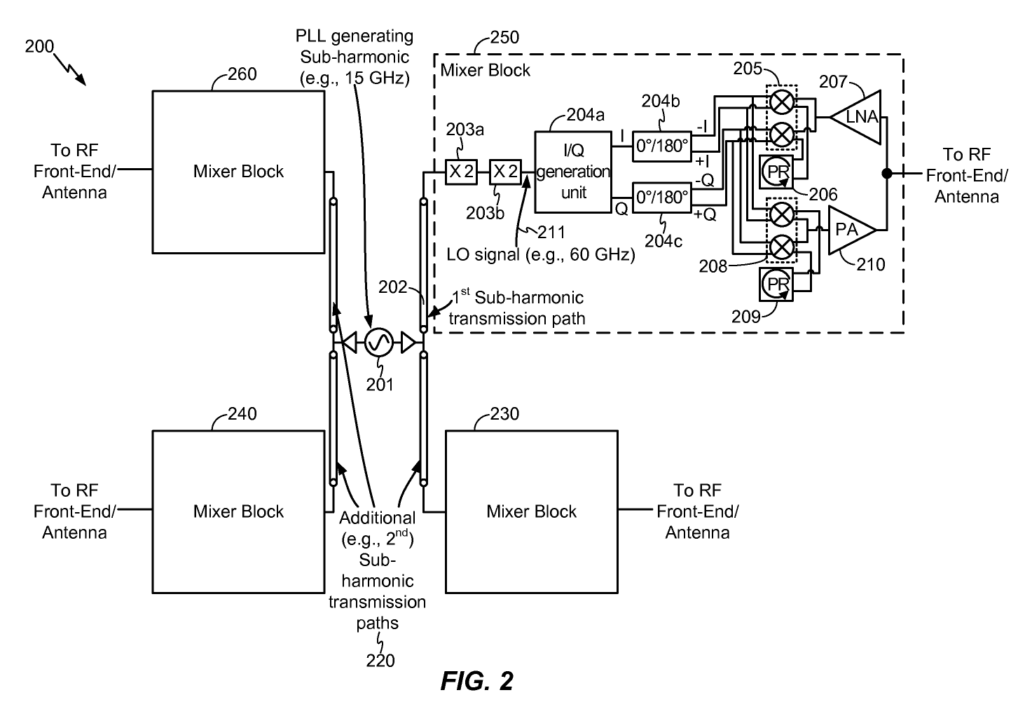

The oscillator 114 may also output the sub-harmonic signal 102 to the frequency upconverter 120. In a particular embodiment, when the sub-harmonic signal 102 is a 1/n sub-harmonic of the LO frequency, the frequency upconverter 120 may frequency upconvert the sub-harmonic signal by a factor of n. For example, the frequency upconverter 120 may upconvert a 15 GHz sub-harmonic signal by a factor of four to generate a LO signal having an LO frequency of 60 GHz. In a particular embodiment, the frequency upconverter 120 may include at least one signal multiplier (e.g., doubler) to perform the upconversion, as further described with reference to FIGS. 2-4.

During operation, the PLL 110 may generate and maintain (via phase and frequency locking) the sub-harmonic signal 102 at a frequency that is a sub-harmonic of a LO frequency. The sub-harmonic signal 102 may be routed to the frequency upconverter 120, which may upconvert the sub-harmonic signal 102 to generate a LO signal 121.

In a particular embodiment, the PLL 110 and the frequency upconverter 120 may be integrated into a radio frequency (RF) beamforming device. It should be noted that RF beamforming is described for illustration only. Methods of beamforming may include, but are not limited to, RF beamforming, baseband beamforming, digital beamforming, and LO beamforming. One or a combination of beamforming methods may be used in conjunction with the described signal generation techniques. As shown in FIG. 1, the RF beamforming device may have a single mixer block that includes the frequency upconverter 120. The sub-harmonic signal 102 may be routed from the PLL 110 to the mixer block, where the sub-harmonic signal 102 may be upconverted by the frequency upconverter 120 to generate the LO signal 121. In another particular embodiment, the PLL 110 and the frequency upconverter 120 may be integrated into a wireless device. For example, when the LO frequency is 60 GHz, the wireless device may be a millimeter wavelength (mmWave) device operable to communicate in accordance with an IEEE 802.11ad protocol, which includes four wireless channels having frequencies between 57 GHz and 66 GHz. In alternate embodiments, the described techniques may be used with other standards that support MIMO or standards without MIMO.

It will be appreciated that by operating the PLL 110 at a lower sub-harmonic frequency rather than at a higher LO frequency, the system 100 of FIG. 1 may result in relaxed design requirements for the PLL 110 and reduced power consumption by the PLL 110. To illustrate, configuring the oscillator 114 to output the lower frequency sub-harmonic signal 102 instead of the higher frequency LO signal 121 may reduce power consumption by the PLL 110, which may enable the PLL 110 to meet power consumption requirements (e.g., design constraints) associated with certain types of devices (e.g., wireless telephones). Configuring the oscillator 114 to output the lower frequency sub-harmonic signal 102 instead of the higher frequency LO signal 121 may also enable the PLL 110 to meet tuning and noise requirements (e.g., design constraints) that are difficult to meet at higher frequencies (e.g., 60 GHz). In addition, routing the sub-harmonic signal 102 to the frequency upconverter 120 may consume less power than routing the LO signal 121 to the frequency upconverter 120. A distance between the PLL 110 and a mixer block that includes the frequency upconverter 120 may be longer than a distance between the frequency upconverter 120 and other components of the mixer block. Because routing a lower frequency signal may consume less power than routing a higher frequency signal, routing the sub-harmonic signal 102 over a longer distance and the LO signal 121 over a shorter distance may result in power savings (e.g., battery power savings in a wireless telephone that incorporates the system 100 of FIG. 1).

Further, the system 100 of FIG. 1 may generate an extremely high frequency (EHF) signal of 60 GHz by a single homodyne (i.e., zero-IF) conversion (e.g., from 15 GHz to 60 GHz) without the use of injection lock oscillators. This may be more robust and/or more power efficient than using a superheterodyne architecture that uses a conversion to an intermediate frequency (e.g., 48 GHz). The system 100 of FIG. 1 may thus provide a single homodyne conversion system to generate frequencies near all four wireless channel frequencies of IEEE 802.11ad over potential PVT variations. In a particular embodiment, the system 100 of FIG. 1 may be used in conjunction with a superheterodyne architecture. For example, a 12 GHz sub-harmonic signal may be generated and routed in a 48 GHz superheterodyne system. In a particular embodiment, a first portion of upconversion to a LO frequency may be performed centrally (e.g., at a PLL output) and a second portion of the upconversion may be performed at routing endpoints (e.g. mixer blocks).

It should be noted that although FIG. 1 depicts routing of a sub-harmonic signal to a single frequency upconverter, a sub-harmonic signal may be routed to multiple endpoints. FIG. 2 is a diagram of a particular embodiment of a MIMO device 200 that is operable to generate a LO frequency at each of a plurality of front-end mixer blocks by upconversion of a sub-harmonic frequency generated by a PLL. As shown in FIG. 2, the MIMO device 200 may be a 4×4 MIMO device that includes a corresponding mixer block 230, 240, 250, and 260 for each of the four input/output (e.g., receiver/transmitter) pairs. However, the illustration of four inputs and four outputs is for example only. The LO frequency generation techniques described herein may also be used in MIMO devices having a different number of receivers and transmitters, such as 2×2 MIMO devices, 8×8 MIMO devices, 32×32 MIMO devices, and other electronic devices. The MIMO device 200 may be configured to receive signals in the same frequency band across all radios. It should be noted that for ease of illustration, only components of the mixer block 250 are illustrated. However, it should be understood that the remaining mixer blocks 230, 240, and 260 may include corresponding components that function as described herein with reference to the components of the mixer block 250.

Each mixer block of the MIMO device 200 may be coupled to a PLL 201 via a corresponding sub-harmonic transmission path of a plurality of sub-harmonic transmission paths. For example, the mixer block 250 may be coupled to the PLL 201 via a first sub-harmonic transmission path 202. In an illustrative embodiment, the PLL 201 may include the PLL 110 of FIG. 1.

The mixer block 250 may include a frequency upconverter, which is illustrated in FIG. 2 as two doublers 203a and 203b. The frequency upconverter may output a LO signal 211 (e.g., having a frequency of 60 GHz) to an I/Q signal generation unit. In FIG. 2, the I/Q signal generation unit is illustrated as a single-ended I/Q signal generation unit 204a, which generates an I signal and a Q signal at the LO frequency, coupled to single-to-differential converters 204b and 204c, which generate +I/−I and +Q/−Q signals, respectively. In embodiments where the I/Q signal generation unit 204a generates differential signals, the single-to-differential converters 204b and 204c may not be present. The I/Q signals may be used for communication in Wi-Fi networks and other IEEE 802.11-based networks. The differential signals may be output to one or more first mixers 205 that are coupled to a first phase rotator 206. For example, the mixer block 250 may be part of a transceiver and the first phase rotator 206 may be used to steer a RF beam. A low noise amplifier (LNA) 207 may also be coupled to the first mixers 205, as shown.

The differential signals may also be output to one or more second mixers 208 that are coupled to a second phase rotator 209. A power amplifier (PA) 210 may also be coupled to the second mixers 208, as shown. The LNA 207 and the PA 210 may be associated with a particular input and a particular output of the MIMO device 200. For example, the LNA 207 and the PA 210 may be connected to a particular RF front end/antenna of the MIMO device 200.

During operation, the PLL 201 may generate a sub-harmonic signal. The sub-harmonic signal may be routed to each of a plurality of mixer blocks (e.g., the mixer block 250 and the additional mixer blocks 230, 240, and 260) via one of a plurality of sub-harmonic transmission paths (e.g., the first sub-harmonic transmission path 202 and one or more second sub-harmonic transmission paths 220). The sub-harmonic signal may be frequency upconverted at each of the mixer blocks, and the resulting LO frequency signal may be used to generate I/Q signals that are provided to other components of the mixer blocks, as shown.

In a particular embodiment, the MIMO device 200 may be integrated into a wireless device. For example, when the LO frequency is 60 GHz, the wireless device may be a millimeter wavelength (mmWave) device operable to communicate in accordance with an IEEE 802.11ad protocol, which includes four wireless channels having frequencies between 57 GHz and 66 GHz.

As shown in FIG. 2, the length of the sub-harmonic transmission paths 202, 220 may be substantially longer than the length between the frequency upconverter and I/Q signal generation unit in the mixer blocks 230-260 (i.e., the distance that the LO frequency signal is routed). Thus, the sub-harmonic signal generated by the PLL 201 may be routed over a first distance (e.g., a length of the first sub-harmonic transmission path 202) that is less than a second distance that the LO signal 211 is routed within the mixer block (e.g., a distance between the doubler 203b and the I/Q signal generation unit 204a). In a particular embodiment, the sub-harmonic routing distance may be longer than the LO routing distance by at least a factor of 2, and possibly longer by as much as a factor of several hundred. By performing local I/Q generation at each mixer block using the sub-harmonic signal instead of routing a centrally-generated high-frequency LO signal or centrally generated high-frequency I/Q signals to each mixer block, the MIMO device 200 of FIG. 2 may provide increased immunity to pulling effects, electromagnetic and substrate coupling (e.g., to sensitive blocks, such as a LNA), and PVT variations. To illustrate, the 15 GHz sub-harmonic signal shown in FIG. 2 may be more immune to frequency pulling effects and PVT variations in phase or amplitude than the 60 GHz LO signal 211 or the 60 GHz I/Q signals. Thus, the 15 GHz sub-harmonic signal may be routed a longer distance than the 60 GHz LO signal 211 or the 60 GHz I/Q signals.

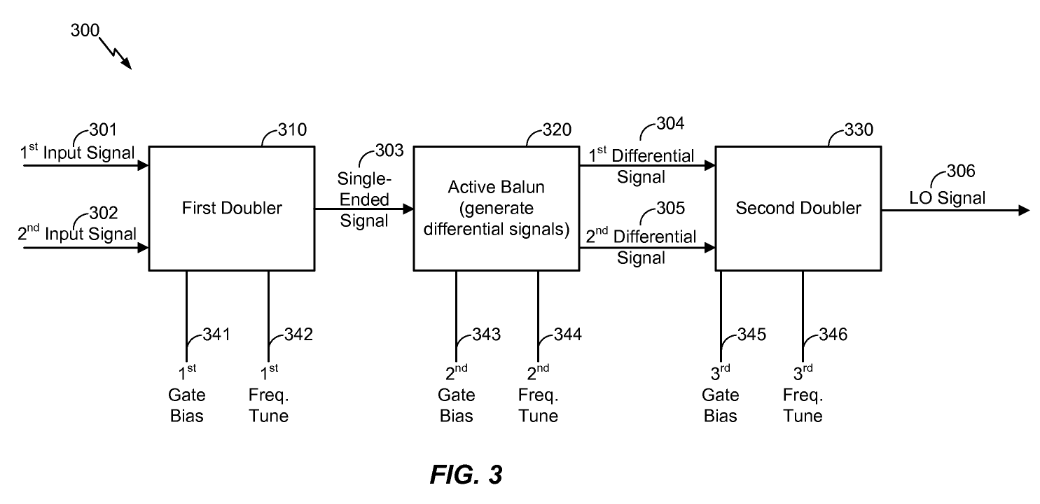

FIG. 3 is a diagram to illustrate a particular embodiment of a system 300 that is operable to upconvert a sub-harmonic frequency to generate a LO frequency. In an illustrative embodiment, the system 300 or components thereof may implement the frequency upconverter 120 of FIG. 1, the frequency upconverter 203 of FIG. 2, or components thereof. The system 300 of FIG. 3 is shown as performing 4× upconversion. It should be noted however that upconversion by factors other than four may also be used.

The system 300 includes a first doubler 310, a balun 320, and a second doubler 330. The first doubler 310 may be configured to receive a first input signals 301 and a second input signal 302 (e.g., differential signals) having a frequency (e.g., 15 GHz) that is one-fourth a LO frequency (e.g., 60 GHz). The first doubler 310 may generate a single-ended signal 303 having a second frequency (e.g., 30 GHz) that is approximately one-half the LO frequency. The balun 320 may generate a first differential signal 304 and a second differential signal 305 from the single-ended signal 303, as shown. The differential signals 304, 305 may be output to the second doubler 330, which may generate a LO signal 306 (e.g., a 60 GHz signal) from the differential signals 304, 305.

When the system 300 of FIG. 3 is integrated into a mixer block, the first doubler 310, the balun 320, and the second doubler 330 may each receive separate gate bias and frequency tuning inputs, as shown. For example, the first doubler 310 may receive a first gate bias input 341 and a first frequency tuning input 342, the balun 320 may receive a second gate bias input 343 and a second frequency tuning input 344, and the second doubler 330 may receive a third gate bias input 345 and a third frequency tuning input 346. The gate bias inputs 341, 343, and 345 may correspond to a common gate bias input for the mixer block or may be different from each other. Similarly, the frequency tuning inputs 342, 344, and 346 may correspond to a common frequency tuning input for the mixer block or may be different from each other. In a particular embodiment, the gate bias inputs 341, 343, and 345 may each be 3 bits long. In a particular embodiment, the frequency tuning inputs 342, 344, and 346 may each be 2 bits long.

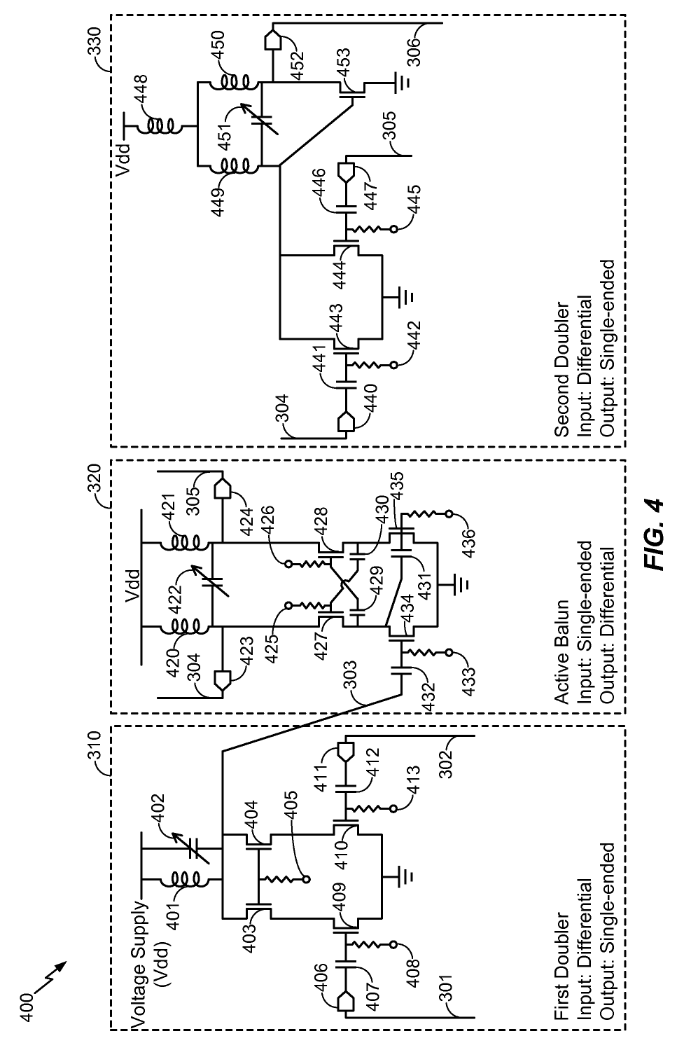

A particular embodiment of a circuit-level implementation of the first doubler 310, the balun 320, and the second doubler 330 is illustrated in FIG. 4 and generally designated 400. As shown in FIG. 4, the first doubler 310 may include a first inductor 401 and a first variable capacitor 402 connected to a voltage supply (Vdd). In a particular embodiment, the voltage supply may supply a positive voltage of 0.9 volts (e.g., Vdd=0.9V). The first doubler 310 may also include a first negative channel field effect transistor (NFET) 403 and a second NFET 404 whose respective gates are connected to a first resistor 405, as shown. The first resistor 405 may be connected to a first bias voltage (e.g., a voltage generated on-chip). The first NFET 403 may also be connected to a third NFET 409, and the second NFET 404 may also be connected to a fourth NFET 410. A first pad 406 may receive the first input signal 301 of FIG. 3 and may be connected to a first capacitor 407. The first capacitor 407 may be connected to a second resistor 408 that is connected to the third NFET 409. A second pad 411 may receive the second input signal 302 of FIG. 3 and may be connected to a second capacitor 412. The second capacitor 412 may be connected to a third resistor 413 that is connected to the fourth NFET 410, as shown. The second resistor 408 and the third resistor 413 may be connected to a second bias voltage (e.g., a voltage generated on-chip). The first doubler 310 may produce the single-ended signal 303 of FIG. 3 as output.

The balun 320 may include a second inductor 420 and a third inductor 421 that are connected to the voltage supply (Vdd) and to a second variable capacitor 422. The balun 320 may also include a fifth NFET 427 and a sixth NFET 428 that are cross-coupled, as shown. A gate of the fifth NFET 427 may be connected to a fourth resistor 425 and to a third capacitor 430. A gate of the sixth NFET 428 may be connected to a fifth resistor 426 and to a fourth capacitor 429. The fourth resistor 425 and the fifth resistor 426 may be connected to a third bias voltage (e.g., a voltage generated on-chip). The single-ended signal 303 may be received at a fifth capacitor 432 that is connected to a sixth resistor 433 and to a seventh NFET 434. A seventh resistor 436 may be connected to a sixth capacitor 431 and to an eighth NFET 435, as shown. The sixth resistor 433 and the seventh resistor 436 may be connected to a fourth bias voltage (e.g., a voltage generated on-chip). A third pad 423 of the balun 320 may produce the first differential signal 304 of FIG. 3 as output and a fourth pad 424 may produce the second differential signal 305 of FIG. 3 as output.

The second doubler 330 may include a fifth pad 440 that receives the first differential signal 304 as input and a sixth pad 447 that receives the second differential signal 305 as input. The fifth pad 440 may be connected to a seventh capacitor 441 that is connected to an eighth resistor 442 and to a ninth NFET 443. The sixth pad 447 may be connected to an eighth capacitor 446 that is connected to a ninth resistor 445 and to a tenth NFET 444. The eighth resistor 442 and the ninth resistor 445 may be connected to a fifth bias voltage (e.g., a voltage generated on-chip). The second doubler 330 may also include a fourth inductor 448, a fifth inductor 449, and a sixth inductor 450 connected between the voltage supply (Vdd) and a third variable capacitor 451, as shown. The fifth inductor 449 may also be connected to a gate of an eleventh NFET 453 that is also connected to a seventh pad 452. The seventh pad 452 may produce the LO signal 306 of FIG. 3 as output.

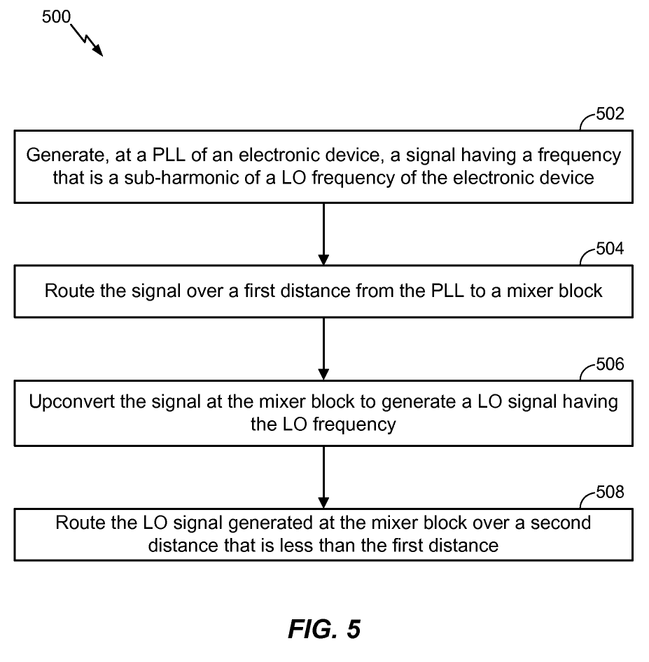

FIG. 5 is a flowchart of a particular embodiment of a method 500 of generating a LO frequency by upconversion of a sub-harmonic frequency. In an illustrative embodiment, the method 500 may be performed by the system 100 of FIG. 1 or the MIMO device 200 of FIG. 2.

The method 500 may include generating, at a PLL of an electronic device, a signal having a frequency that is a sub-harmonic of a LO frequency of the electronic device, at 502. For example, in FIG. 1, the PLL 110 may generate the sub-harmonic signal 102.

The method 500 may also include routing the signal over a first distance from the PLL to a mixer block, at 504. For example, in FIG. 1, the sub-harmonic signal 102 may be routed over a first distance from the PLL 110 to a mixer block that includes the frequency upconverter 120. In a particular embodiment, the first distance may be a length of the first sub-harmonic transmission path 202 of FIG. 2.

The method 500 may further include upconverting the signal at the mixer block to generate an LO signal having the LO frequency, at 506. For example, in FIG. 1, the frequency upconverter 120 may upconvert the sub-harmonic signal 102 to generate the LO signal 121.

The method 500 may include routing the LO signal generated at the mixer block over a second distance that is less than the first distance, at 508. For example, referring to FIG. 2, the LO signal 211 may be routed over a second distance between the doubler 203b and the I/Q signal generation unit 204a, where the second distance is less than the first distance (e.g., the length of the first sub-harmonic transmission path 202).

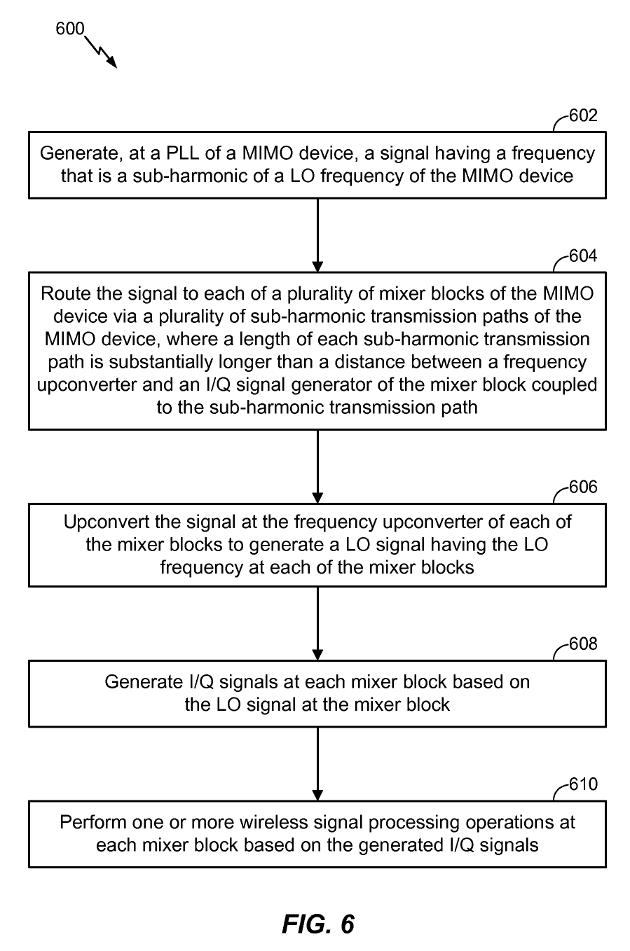

FIG. 6 is a flowchart of another particular embodiment of a method 600 of generating a LO frequency by upconversion of a sub-harmonic frequency. In an illustrative embodiment, the method 600 may be performed by the MIMO device 200 of FIG. 2.

The method 600 may include generating, at a PLL of a MIMO device, a signal having a frequency that is a sub-harmonic of a LO frequency of the MIMO device, at 602. For example, in FIG. 2, the PLL 201 may generate the 15 GHz sub-harmonic signal that is a 1/4 sub-harmonic of the 60 GHz LO frequency of the MIMO device 200.

The method 600 may also include routing the signal to each of a plurality of mixer blocks of the MIMO device via a plurality of sub-harmonic transmission paths of the MIMO device, at 604. A length of each sub-harmonic transmission path may be substantially longer than a distance between a frequency upconverter and an I/Q signal generation unit of the mixer block coupled to the sub-harmonic transmission path. For example, in FIG. 2, the 15 GHz sub-harmonic signal may be routed to the mixer block 250 via the first sub-harmonic transmission path 202, and the first sub-harmonic transmission path 202 may be longer than the LO routing distance within the mixer block 250.

The method 600 may further include upconverting the signal at the frequency upconverter of each of the mixer blocks to generate a LO signal having the LO frequency at each of the mixer blocks, at 606. For example, in FIG. 2, the doublers 203a and 203b may upconvert the 15 GHz sub-harmonic signal to generate the 60 GHz LO signal 211. In an illustrative embodiment, the upconversion may be performed as described with reference to the system of FIG. 3 (illustrated at a circuit level in FIG. 4).

The method 600 may include generating I/Q signals at each mixer block based on the LO signal at each mixer block, at 608, and performing one or more wireless signal processing operations at each mixer block based on the generated I/Q signals, at 610. For example, in FIG. 2, the I/Q signal generation unit 204a and the single-to-differential converters 204b and 204c may generate I/Q signals that are provided to the first mixers 205 and the second mixers 208 for performing wireless signal processing operations (e.g., beamforming, mixing, amplifying, etc.). It should be noted that although I/Q generation at the LO frequency is described, this is for illustration only. Alternate embodiments of systems may not involve I/Q signal processing. Thus, I/Q generation may be skipped in such embodiments.

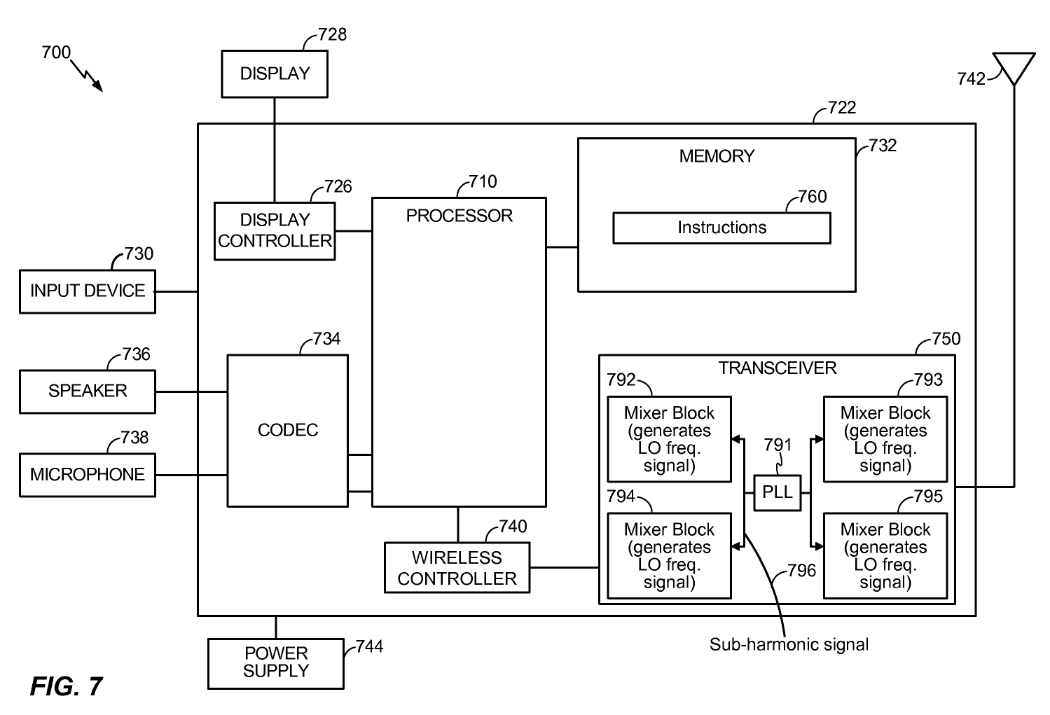

FIG. 7 is a block diagram of a mobile communication device 700. All or part of the methods described in FIGS. 5-6 may be performed at or by the mobile communication device 700. The mobile communication device 700 includes a processor 710, such as a digital signal processor (DSP), coupled to a memory 732.

The memory 732 may be a non-transitory tangible computer-readable and/or processor-readable storage device that stores instructions 760. The instructions 760 (and other instructions associated with other components of the device 700, such as firmware associated with a controller) may be executable (e.g., by the processor 710 or other component of the device 700) to initiate, control, or perform the methods described with reference to FIGS. 5-6 and/or other methods and functions described herein. FIG. 7 also shows a display controller 726 that is coupled to the processor 710 and to a display device 728. A coder/decoder (CODEC) 734 can also be coupled to the processor 710. A speaker 736 and a microphone 738 can be coupled to the CODEC 734.

FIG. 7 also indicates that a wireless controller 740 can be coupled to the processor 710, where the wireless controller 740 is in communication with one or more antennas 742 via a transceiver 750. The wireless controller 740, the transceiver 750, and the antenna(s) 742 may thus represent a wireless interface that enables wireless communication by the mobile communication device 700. The mobile communication device 700 may include numerous wireless interfaces, where different wireless networks are configured to support different networking technologies or combinations of networking technologies.

The transceiver 750 may include a PLL 791 that is connected to a plurality of front-end mixer blocks, such as illustrative mixer blocks 792, 793, 794, and 795. In an illustrative embodiment, the PLL 791 may be the PLL 110 of FIG. 1 or the PLL 201 of FIG. 2, and the mixer blocks 792-795 may each include the frequency upconverter 120 of FIG. 1, one or more components of the mixer block 250 of FIG. 2, the upconversion system 300 of FIG. 3, the circuit 400 of FIG. 4, or any combination thereof. As described with reference to FIGS. 1-6, the PLL 791 may generate a sub-harmonic signal 796 that is routed to each of the mixer blocks 792-795. The mixer blocks 792-795 may each upconvert (e.g., multiply) the sub-harmonic signal 796 to generate a LO signal. The LO signal may be used for I/Q signal generation and/or wireless signal processing operations at the transceiver 750. In a particular embodiment, the transceiver 750 may enable the mobile communication device 700 to operate as a MIMO mmWave device (e.g., each of the mixer blocks 792-795 may generate a LO signal having a frequency of approximately 60 GHz). As described with reference to FIGS. 1-6, centrally generating the lower frequency sub-harmonic signal 796 at the PLL 791 and routing the sub-harmonic signal 796 to each of the mixer blocks 792-795 may consume less power than centrally generating and routing a higher frequency LO signal to each of the mixer blocks 792-795. For example, less power from a power supply 744 (e.g., a battery) may be consumed.

In a particular embodiment, the processor 710, the display controller 726, the memory 732, the CODEC 734, the wireless controller 740, and the transceiver 750 are included in a system-in-package or system-on-chip device 722. In a particular embodiment, an input device 730 and the power supply 744 are coupled to the system-on-chip device 722. Moreover, in a particular embodiment, as illustrated in FIG. 7, the display device 728, the input device 730, the speaker 736, the microphone 738, the antenna(s) 742, and the power supply 744 are external to the system-on-chip device 722. However, each of the display device 728, the input device 730, the speaker 736, the microphone 738, the antenna(s) 742, and the power supply 744 can be coupled to a component of the system-on-chip device 722, such as an interface or a controller.

In conjunction with the described embodiments, an apparatus is disclosed that may include means for outputting a signal having a frequency that is a sub-harmonic of a LO frequency. For example, the means for outputting may include the PLL 110 of FIG. 1, the PLL 201 of FIG. 2, the PLL 791 of FIG. 7, another device or circuit configured to output a signal, or any combination thereof. The apparatus may also include a plurality of mixer blocks, where each mixer block of the plurality of mixer blocks includes means for upconverting the signal to generate a LO signal having the LO frequency. For example, the means for upconverting may include the frequency upconverter 120 of FIG. 1, the frequency upconverter 203 of FIG. 2, the system 300 of FIG. 3, the circuit 400 of FIG. 4, one or more components of the mixer blocks 792-795 of FIG. 7, another device or circuit configured to upconvert a signal, or any combination thereof.

The apparatus may further include means for routing the signal to each of the plurality of mixer blocks. For example, the means for routing may include the sub-harmonic transmission path 202 of FIG. 2, one of the sub-harmonic transmission paths 220 of FIG. 2, another device or circuit configured to route a signal, or any combination thereof. The apparatus may include means for generating I/Q signals at the LO frequency. For example, the means for generating may include the I/Q signal generation unit 204 of FIG. 2, another device or circuit configured to generate I/Q signals, or any combination thereof. In a particular embodiment, the means for outputting, the means for upconverting, the means for routing, and the means for generating may be integrated into a MIMO device. For example, each of the mixer blocks may be associated with a particular input and a particular output (e.g., a particular RF front-end/antenna in FIG. 2) of the MIMO device.

Those of skill would further appreciate that the various illustrative logical blocks, configurations, modules, circuits, and algorithm steps described in connection with the embodiments disclosed herein may be implemented as electronic hardware, computer software, or combinations of both. Various illustrative components, blocks, configurations, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transitory storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal (e.g., a mobile phone or a PDA). In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments disclosed herein but is to be accorded the widest scope possible consistent with the principles and novel features as defined by the following claims.

What is claimed is:

1. An apparatus for generating a local oscillator signal, the apparatus comprising:
a phase-locked loop (PLL) configured to output a signal having a frequency that is a sub-harmonic of a local oscillator (LO) frequency; and
a mixer block including a frequency upconverter configured to upconvert the signal to generate a LO signal having the LO frequency.

2. The apparatus of claim 1, wherein the LO frequency is approximately 60 gigahertz (GHz).

3. The apparatus of claim 1, wherein the frequency upconverter includes at least one signal multiplier.

4. The apparatus of claim 1, wherein the PLL and the frequency upconverter are integrated into a device operable to communicate in accordance with an Institute of Electrical and Electronics Engineers (IEEE) 802.11ad protocol.

5. The apparatus of claim 1, further comprising:
a first sub-harmonic transmission path of a multiple-input multiple-output (MIMO) device configured to route the signal from the PLL to the frequency upconverter; and
one or more second sub-harmonic transmission paths configured to route the signal from the PLL to one or more second frequency upconverters included in one or more second mixer blocks of the MIMO device.

6. An apparatus for generating a local oscillator signal, the apparatus comprising:
a multiple-input multiple-output (MIMO) device comprising:
a phase-locked loop (PLL) configured to output a signal having a frequency that is a sub-harmonic of a local oscillator (LO) frequency;
a plurality of mixer blocks, wherein each mixer block of the plurality of mixer blocks is associated with a particular input and a particular output of the MIMO device and includes a frequency upconverter configured to upconvert the signal to generate a LO signal having the LO frequency; and
a plurality of sub-harmonic transmission paths, wherein each sub-harmonic transmission path of the plurality of sub-harmonic transmission paths is configured to route the signal to a mixer block of the plurality of mixer blocks.

7. The apparatus of claim 6, wherein the frequency is approximately one-fourth the LO frequency, and wherein the frequency upconverter comprises:
a first doubler configured to receive a first input signal and a second input signal having the frequency and to generate a single-ended signal having a second frequency that is approximately one-half the LO frequency;
a balun configured to generate differential signals having the second frequency from the single-ended signal; and
a second doubler configured to generate the LO signal from the differential signals.

8. The apparatus of claim 6, wherein at least one of the mixer blocks includes an in-phase/quadrature-phase (I/Q) signal generation unit coupled to the frequency upconverter and configured to generate I/Q signals at the LO frequency.

9. The apparatus of claim 8, wherein a length of each of the sub-harmonic transmission paths is substantially larger than a distance between the frequency upconverter and the I/Q signal generation unit.

10. The apparatus of claim 8, wherein the at least one mixer block further includes:
one or more first mixers coupled to the I/Q signal generation unit;
a first phase rotator coupled to the one or more first mixers;
a low noise amplifier (LNA) coupled to the one or more first mixers;
one or more second mixers coupled to the I/Q signal generation unit;
a second phase rotator coupled to the one or more second mixers; and
a power amplifier (PA) coupled to the one or more second mixers.

11. The apparatus of claim 8, wherein the MIMO device is integrated into a millimeter wavelength (mmWave) device.

12. A method for generating a local oscillator signal, the method comprising:
generating, at a phase-locked loop (PLL) of an electronic device, a signal having a frequency that is a sub-harmonic of a local oscillator (LO) frequency of the electronic device; and
upconverting the signal at a mixer block to generate a LO signal having the LO frequency.

13. The method of claim 12, wherein the LO frequency is approximately 60 gigahertz (GHz).

14. The method of claim 12, further comprising routing the signal from the PLL to the mixer block.

15. The method of claim 14, wherein the signal is routed over a first distance from the PLL to the mixer block and wherein the LO signal generated at the mixer block is routed within the mixer block over a second distance that is less than the first distance.

16. A method for generating a local oscillator signal, the method comprising:
generating, at a phase-locked loop (PLL) of a multiple-input multiple-output (MIMO) device, a signal having a frequency that is a sub-harmonic of a local oscillator (LO) frequency of the MIMO device;
routing the signal to each of a plurality of mixer blocks of the MIMO device via a corresponding one of a plurality of sub-harmonic transmission paths of the MIMO device; and
upconverting the signal at each of the plurality of mixer blocks to generate a LO signal having the LO frequency at each of the plurality of mixer blocks.

17. The method of claim 16, further comprising generating in-phase/quadrature-phase (I/Q) signals at an I/Q signal generation unit of each mixer block based on the LO signal at the mixer block.

18. The method of claim 17, wherein a length of each sub-harmonic transmission path of the plurality of sub-harmonic transmission paths is substantially longer than a distance between a frequency upconverter and the I/Q signal generation unit of the mixer block coupled to the sub-harmonic transmission path.

19. The method of claim 17, further comprising performing one or more wireless signal processing operations based on the generated I/Q signals.

20. An apparatus for generating a local oscillator signal, the apparatus comprising:
a multiple-input multiple-output (MIMO) device comprising:
means for outputting a signal having a frequency that is a sub-harmonic of a local oscillator (LO) frequency;
a plurality of mixer blocks, wherein each mixer block of the plurality of mixer blocks is associated with a particular input and a particular output of the MIMO device and includes means for upconverting the signal to generate a LO signal having the LO frequency; and
means for routing the signal to each of the plurality of mixer blocks.

21. The apparatus of claim 20, wherein at least one of the mixer blocks comprises means for generating in-phase/quadrature-phase (I/Q) signals at the LO frequency.

22. A non-transitory processor-readable medium comprising instructions that, when executed by a multiple-input multiple-output (MIMO) device, cause the MIMO device to:
generate, at a phase-locked loop (PLL), a signal having a frequency that is a sub-harmonic of a local oscillator (LO) frequency of the MIMO device;
route the signal to each of a plurality of mixer blocks of the MIMO device via a corresponding one of a plurality of transmission paths of the MIMO device; and
upconvert the signal at each of the plurality of mixer blocks to generate a LO signal having the LO frequency at each of the plurality of mixer blocks.

23. The non-transitory processor-readable medium of claim 22, further comprising instructions that, when executed by the MIMO device, cause the MIMO device to:
generate, at an I/Q signal generation unit of each mixer block, in-phase/quadrature-phase (I/Q) signals at the LO frequency based on the LO signal at the mixer block; and
perform one or more wireless signal processing operations based on the generated I/Q signals.
